(19) United States
(12) Patent Application Publication
(10) Pub. No.: US 2016/0252577 A1
(43) Pub. Date: Sep. 1, 2016

(54) DEVICE AND METHOD FOR CHECKING A SWITCHING OPERATION OF AN ELECTRIC SWITCH

(71) Applicant: OMICRON ELECTRONICS GMBH, Klaus (AT)

(72) Inventor: Daniel Walch, Feldkirch (AT)

(73) Assignee: Omicron Electronics GmbH, Klaus (AT)

(21) Appl. No.: 15/027,631

(22) PCT Filed: Oct. 7, 2014
(86) PCT No.: PCT/EP2014/071410

§ 371 Date: Apr. 6, 2016

(30) Foreign Application Priority Data
Oct. 7, 2013 (EP) 13187485.1

(51) Int. Cl. G01R 31/327; G01D 5/12

(52) U.S. Cl. CPC G01R 31/3274; G01D 5/12; G01R 31/3275

(57) ABSTRACT

In order to check a switching operation of an electric switch (1-3), a movement of a movable switching element (1) of the electric switch (1-3) is sensed during the switching operation. For that purpose, a marking element (11) is used, the marking element (11) having a magnetization pattern comprising a plurality of magnetic markings. A path length (9) of a relative movement between the marking element (11) and a sensor (12) is determined.

### TECHNICAL FIELD OF THE INVENTION

The invention relates to methods and devices for checking a switching operation of an electric switch. The invention relates in particular to methods and devices for checking opening and closing operations of electric extra-high-, high- or medium-voltage switches.

### BACKGROUND OF THE INVENTION

Electric power switches and load switches, such as e.g. extra-high-, high- or medium-voltage switches, must be checked after a new installation, after a modification or on an inspection before they can be put into operation for the first time or again. An important check in this regard is the inclusion of a so-called path-time diagram. This makes it possible in particular to check whether the opening operation or closing operation of the switch takes place fast enough and/or whether at the end of a path a braking of a movable switching element of the switch is effected in the desired manner.

In conventional methods and devices a path sensor or an angle sensor can be attached for this purpose between the movable switching element of the switch and a fixed part of the switch. With the aid of a suitable testing device, the path or the angle can be plotted against time during the switching operation and, with the aid of the path-time or angle-time diagram thus determined, all necessary further analyses can be performed. The attaching of the path or angle sensor in conventional devices and methods may prove to be relatively expensive and complicated.

Further methods and devices use, for example, a plurality of optical markings. The consistent application of a plurality of markings to a difficultly accessible movable switching element may likewise be difficult.

### BRIEF SUMMARY OF THE INVENTION

The object on which the invention is based therefore is to provide improved methods and devices for checking a switching operation of an electric switch, which in particular simplify assembly and, even when there is little space available in the surrounding area of the movable parts of the switch, are easily usable and operable.

In a method for checking a switching operation of an electric switch according to an exemplary embodiment, a movement of a movable switching element of the electric switch during the switching operation is sensed. In doing so, a marking element comprising a magnetization pattern having a plurality of magnetic markings is used. The sensing of the movement of the movable switching element comprises determining a path length of a relative movement between the marking element and a sensor.

By using a marking element which already has a plurality of magnetic markings in a magnetization pattern, the assembly of the elements required for sensing the movement can be simplified. The marking element in combination with the sensor allows, owing to the plurality of magnetic markings, the determination of the relative movement between the marking element and the sensor. A reliable determination of the path length of the relative movement can also be effected, owing to the magnetic position coding and/or movement coding, if during the test of the switch the marking element cannot be optically detected, for example, due to unfavourable light conditions.

The marking element can be attached to the electric switch by a detachable holding means. The marking element can be reversibly detachably attached, so that it can be removed again without destruction of the marking element and/or the component of the electric switch to which the marking element is fastened.

The marking element can be reversibly detachably attached to the movable switching element. The marking element can be reversibly detachably attached to a component of the switch, which component moves on the movement of the movable switching element. This makes it possible to attach a relatively compact, passive component for sensing the movement of the switching element to a movable part of the electric switch. Such an attachment of the marking element can be easily carried out even with limited accessibility of the moving part.

The magnetization pattern can have a pattern of magnetic markings periodically repeating along a direction. The direction along which the periodically repeating pattern extends can be arranged parallel to a movement direction of the movable switching element.

The magnetization pattern can be absolutely coded. That is to say, the magnetization pattern can be coded in such a way that the sensor can also determine the absolute position of the magnetization pattern relative to the sensor and not only a change of position relative to the sensor.

The sensor can be detachably fastened to a fixed frame of the electric switch. The sensor can be fastened to the fixed frame of the electric switch so that it can be non-destructively removed from the frame again.

The sensor can be fastened to the frame by a lockable movable fastening device and positioned in the vicinity of the marking element. The fastening device facilitates the fastening and positioning of the sensor in particular if the movable switching element is difficult to access.

The fastening device can comprise a movable arm. The movable arm can comprise at least one rigid element and at least one lockable ball joint. The movable arm can comprise a plurality of rigid elements which are connected by at least one lockable ball joint. The movable arm can comprise a holder for fastening the arm to the frame of the switch.

The fastening device can comprise at least one further arm for supporting the sensor, by which the sensor is stabilised in the method.

The marking element can consist of permanent-magnetic material or comprise a permanent-magnetic material. The coding of a relative position or a relative movement can be effected, for example, by a changing polarity of a magnetic field at the surface of the marking element facing the sensor. For example, the marking element can have a plurality of permanent-magnetic sections which have alternatingly a north magnetization and a south magnetization at the surface facing the sensor. More complex patterns may also be used, for example for an absolute position coding.

According to a further exemplary embodiment, a device for checking a switching operation of an electric switch is specified. The electric switch has a movable switching element. The device comprises a marking element having a magnetization pattern comprising a plurality of magnetic markings. The device comprises a sensor for sensing a relative movement between the marking element and the sensor. The device comprises a processing unit which is coupled to the sensor and which is adapted to determine a path length of the relative movement sensed by the sensor.

The device facilitates the sensing of the movement of the movable switching element, since a plurality of magnetic markings are combined on the marking element, which marking element can be attached to a movable part of the electric switch.

The device can comprise a holding means for reversibly detachably attaching the marking element to the movable switching element. The device can comprise a holding means for reversibly detachably attaching the marking element to a component of the electric switch, which component moves on a movement of the movable switching element.

The marking element can consist of a permanent-magnetic material or can comprise a permanent-magnetic material.

The magnetization pattern can have a pattern of magnetic markings periodically repeating along a direction. The marking element can have a plurality of permanent-magnetic sections which have alternatingly a north magnetization and a south magnetization at the surface facing the sensor.

The magnetization pattern can be absolutely coded.

The device can comprise a lockable movable fastening device for detachably fastening the sensor to a frame of the electric switch.

The fastening device can comprise a movable arm which comprises at least one rigid element and at least one lockable ball joint.

The fastening device can comprise at least one further arm for supporting the sensor.

In methods and devices according to exemplary embodiments, the marking element can be flexible. This facilitates the attachment of the device on use in the field and allows use with different types of switches. For example, the marking element can be deformable so that it can be attached both on a flat surface and on a curved surface of a movable part of the electric switch.

The marking element can have a thickness which can be much smaller than a length of the marking element. The marking element can be a strip.

In methods and devices according to exemplary embodiments, the marking element can be a passive element.

In methods and devices according to exemplary embodiments, the movement of the movable switching element relative to the sensor can be sensed. The sensing of the movement can be effected in a time-resolved manner. For a sensor fastened stationarily to an immovable part of the switch, the relative movement between the switching element and the sensor also defines the relative movement between the switching element and a fixed part of the electric switch. With the thus determined information on acceleration, velocity and position of the switching element, the switching operation, in particular an opening operation and/or a closing operation of the electric switch can be analysed. In particular, it can be checked whether the opening operation or closing operation of the switch takes place fast enough and whether at the end of the operation a braking of the switching element is effected in the desired manner.

The processing unit can be adapted to determine automatically, depending on the determined path length of the relative movement, whether an opening operation and/or a closing operation of the electric switch satisfies predetermined quality criteria. The processing unit can be adapted to generate automatically, depending on the determined path length of the relative movement, a warning if the movement sequence indicates that the electric switch has to be replaced or serviced.

In devices and methods according to exemplary embodiments, the sensor is positioned, by means of a fastening device which can comprise a movable arm, in front of the marking element in such a way that it can readily sense the position or the movement of the marking element. The arm, in a state in which it is not fixed, should if possible have a plurality of degrees of freedom, in order to adjust the position of the sensor as optimally as possible. The arm, in a state in which it is fixed, should be as rigid as possible in order that the sensor vibrates during the movement of the switch as little as possible with respect to the fixed parts of the switch.

The movable arm can consist of a construction of rigid parts and ball joints which can preferably be fixed by locking screws in a freely selectable position. A further arm or a plurality of further arms can be used to fix the sensor additionally in the vicinity of the marking element, in order to suppress the vibrations of the sensor with respect to the fixed parts of the switch.

A system according to an exemplary embodiment comprises an electric switch and a device according to an exemplary embodiment, which is attached to the electric switch.

The present invention is explained below with reference to the drawings using preferred embodiments. In the drawings, identical reference symbols designate identical elements.

### BRIEF DESCRIPTION OF THE DRAWINGS

FIG. 1 shows a schematic representation of a device according to an exemplary embodiment, in which a marking element is attached to a linearly moving part of the electric switch.

FIG. 2 shows a schematic representation of a device according to an exemplary embodiment, in which a marking element is attached to a rotationally moving part of the electric switch.

FIG. 3 illustrates a marking element of a device according to an exemplary embodiment, which element is reversibly detachably fastened by a holding means.

FIG. 4 illustrates a marking element of a device according to a further exemplary embodiment, which element is reversibly detachably fastened by a holding means.

FIG. 5 illustrates a marking element of a device according to an exemplary embodiment, which element comprises a pattern of periodically repeating magnetic markings.

FIG. 6 illustrates a marking element of a device according to an exemplary embodiment, which element is absolutely coded.

### DETAILED DESCRIPTION OF EMBODIMENTS OF THE INVENTION

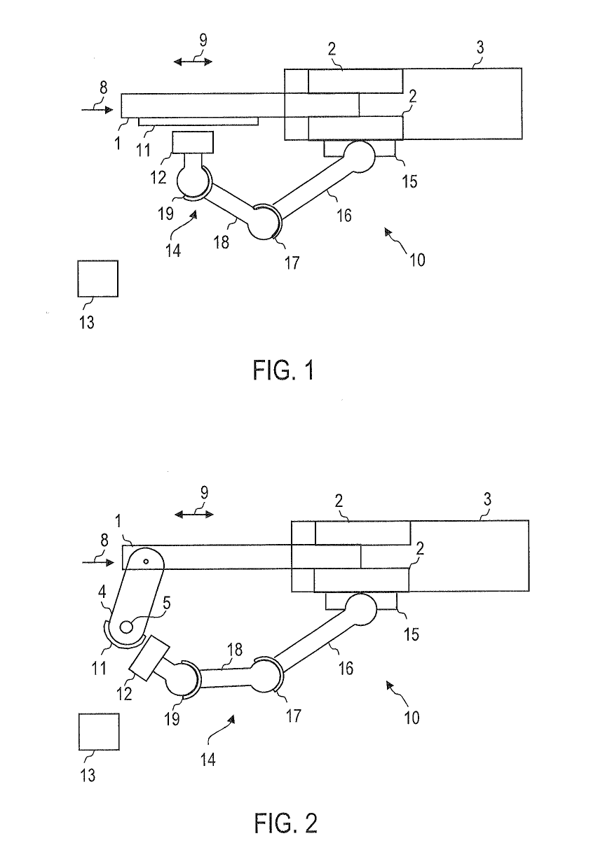

FIG. 1 shows a device 10 for checking a switching operation of an electric switch. The electric switch may be, for example, an electric extra-high-, high- or medium-voltage switch. The electric switch may comprise a switching chamber 3, in which fixed contacts 2 are arranged stationarily relative to the switching chamber 3. The fixed contacts 2 may, for example, be mechanically connected to the switching chamber 3. A movable switching element 1 of the electric switch can project through an opening of the switching chamber 3 into the switching chamber 3 in such a way that on a movement of the movable switching element 1 in a movement direction 8 an electrical contact between the fixed contacts 2 and the movable switching element 1 can be selectively made or broken.

The device 10 serves for checking the correct functioning of the electric switch. The device 10 comprises a marking element 11 having a magnetization pattern comprising a plurality of magnetic markings. The plurality of magnetic markings may comprise, for example, sections of different polarity of the magnetic field and/or of different magnetic field strength and/or of different magnetic field distributions, as will be described in greater detail. A sensor 12 is positioned in a vicinity of the marking element 11. The sensor 12 is adapted so that it can detect at least a relative movement between the sensor 12 and the marking element 11. The sensor 12 can be adapted so that it can detect an absolute position of the marking element 11 relative to the sensor 12. For that purpose, the magnetization pattern of the marking element 11 can be absolutely coded.

For checking the switching operation, the marking element 11 is attached to a movable part of the switch. The marking element 11 can be attached to the movable switching element 1. The movable switching element 1 can carry a switching contact. The marking element 11 can be attached to the movable switching element 1 in such a way that a direction, along which the marking element has a plurality of different magnetic markings, is parallel to the movement direction 8 of the movable switching element 1. The marking element 11 can be reversibly detachably attached to the switching element 11. This allows, after completion of the checking of the electric switch, the marking element 11 to be removed from the electric switch and optionally used for checking a further electric switch.

The sensor 12 can be fastened to a stationary part of the electric switch. A fastening device 14 can be used to fasten the sensor 11 to the frame of the switch, for example to the switching chamber 3. The fastening device 14 can be configured so that it has at least one degree of freedom of movement and advantageously a plurality of degrees of freedom of movement, but is lockable. This facilitates the positioning of the sensor 12 in the vicinity of the marking element 11.

The fastening device 14 may, for example, have an arm which comprises a plurality of rigid elements 16, 18 and at least one lockable ball joint 17, 19. A holder 15 is configured so that it allows a fastening of the arm to a stationary part of the electric switch. The holder 15 can be adapted for a reversibly detachable fastening to a stationary part of the electric switch. A rigid element 16 of the arm can be mounted on the holder 15. The rigid element 16 can be mounted on the holder 15 via a lockable ball joint. A further rigid element 18 can be connected to the rigid element 16 via a lockable ball joint 17. The sensor 12, which can be integrated in a reading head, can be mounted on the further rigid element 18 via a further lockable ball joint 19. To fasten the sensor 12 for data capture, the rigid elements can be firstly positioned and the ball joints then locked in such a way that the sensor 12 is arranged in the vicinity of the marking element 11. The fixing of the ball joints may be effected, for example, with fixing screws. A predetermined side of the sensor 12 can be aligned with the direction 8 along which the movable switching element 1 is movable.

The sensor 12 is connected to a processing unit 13 via a wireless or wired data line. The processing unit 13 can determine, from the relative movement sensed by the sensor 12 between the movable switching element 1 and the sensor 12, the path length 9 of the relative movement. The processing unit 13 can determine the path length 9 of the relative movement in a time-resolved manner. The processing unit 13 can be adapted to determine an acceleration, velocity and/or position of the movable switching element 1 by calculation. The processing unit 13 can be adapted to determine a path-time diagram on the basis of the output signal of the sensor 12.

The processing unit 13 can be adapted to analyse the acquired data automatically, in order to assess the opening operation and/or the closing operation of the electric switch. For example, the processing unit 13 may be adapted to check whether the opening operation or closing operation of the switch takes place fast enough, and/or whether at the end of the operation a braking of the switching element is effected in the desired manner.

The processing unit 13 can have an interface for coupling to a drive of the electric switch. Via the interface, the processing unit 13 can trigger a switching operation and/or recognise when a switching operation of the electric switch for checking the switch is triggered.

The marking element 11 does not have to be attached to the movable switching element 1, but may also be attached to another movable part of the electric switch, as shown in FIG. 2.

FIG. 2 shows the device 10 which is used in an electric switch, the switching element 1 of which can be driven via a pivotably mounted lever 4. The lever 4 can have an axle or a shaft 5. The marking element 11 is attached to the lever 4, thus to a rotating part of the electric switch.

The processing unit 13 can be adapted to analyse the angular movement of the lever 4. The processing unit 13 can be adapted to convert the angular movement, sensed by the sensor 12, of the rotatably mounted part 4 of the electric switch into the corresponding path length 9, by which the movable switching element 1 moves. The corresponding information on the geometry of the respective electric switch can be stored non-volatilely in a memory of the processing unit 13. The processing unit 13 can determine the path length 9 of the relative movement in a time-resolved manner. The processing unit 13 can be adapted to determine an acceleration, velocity and/or position of the movable switching element 1 by calculation. The processing unit 13 can be adapted to determine a path-time diagram on the basis of the output signal of the sensor 12.

If the marking element 11 is attached to a rotatably mounted part 4 of the electric switch, the direction along which the marking element 11 is position-coded can be positioned perpendicularly to the axis of rotation 5 of the rotatably mounted part 4 and at least partly rotate about the axis of rotation 5.

As also shown in FIG. 2, the marking element 11 can be configured so that it can also be attached to a curved surface. The marking element 11 may have a thickness which is much smaller than a length of the marking element 11 along the longest side of the marking element 11. The marking element 11 may be configured as a strip which is flexible.

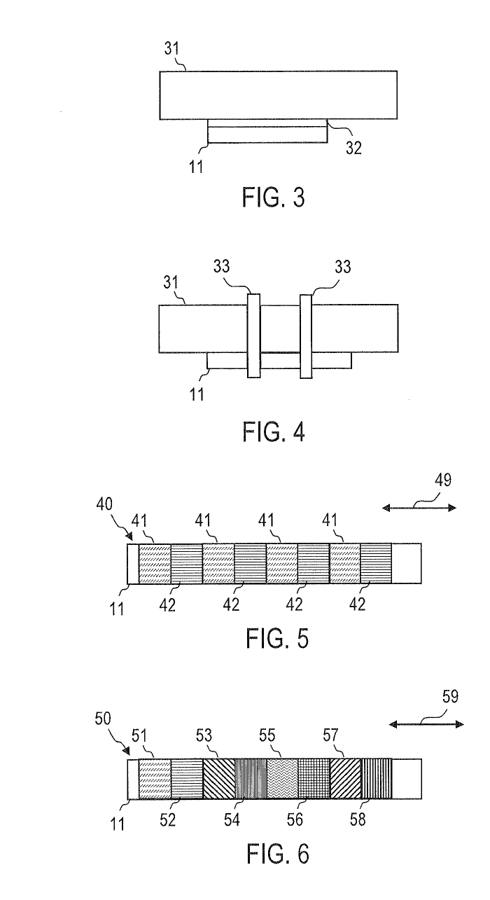

The marking element 11 can be attached to a movable part of the electric switch in different ways, as explained in more detail with the aid of FIG. 3 and FIG. 4.

FIG. 3 shows a marking element 11 of a device 10, which element is attached to a movably mounted part 31 of the electric switch by a holding means 32. The movably mounted part 31 may be, for example, the movable switching element 11 or another component of the electric switch which, on a movement of the electric switching element 1, also moves.

The holding means 32 may comprise an adhesive. The holding means 32 may comprise an adhesive tape or be an adhesive tape. The holding means 32 may consist of a flexible material in order to facilitate the selective fastening of the marking element on plane or curved surfaces.

The holding means 32 can be configured so that the marking element 11 can be reversibly detachably attached to the movably mounted part 31 of the electric switch. The holding means 32 can, in particular, be configured so that the marking element and the movably mounted part 31 of the electric switch are not destroyed when the marking element 11 is removed from the movably mounted part 31 of the electric switch.

FIG. 4 shows a marking element 11 of a device 10, which element is attached in a frictionally engaged manner to the movably mounted part 31 of the electric switch by holding means 33. The holding means 33 can consist of a non-magnetic material. The holding means 33 can each have a locking mechanism, so that they annularly surround the movably mounted part 31 and the marking element lying thereon. The holding means 33 can be openable so that the marking element 11 can be reversibly detachably attached to the movably mounted part 31 of the electric switch. The holding means 33 can, in particular, be configured so that the marking element 11 and the movably mounted part 31 of the electric switch are not destroyed when the holding means 33 are opened and the marking element 11 is removed from the movably mounted part 31 of the electric switch.

The marking element, with which the movable switching element 1 or another movable part of the electric switch can be marked for path length measurement, can be coded in different ways. This is described in more detail with reference to FIG. 5 and FIG. 6.

FIG. 5 shows a marking element 11 having a magnetization pattern 40. The magnetization pattern 40 has a periodic sequence of sections 41, 42 of different magnetization. The sections 41, 42 alternate along a direction 49. In the use of the device 10, the direction 49 can be aligned with the movement direction 8 of the movable switching element 1. On attachment to a rotatably mounted part 4 of the electric switch, the longitudinal direction 49 of the marking element 11 can at least partly rotate about the axis of rotation 5.

The sections 41, 42 which form different magnetic markings can be permanent-magnetic. The sections 41, 42 which form different magnetic markings may differ with regard to the polarity of the magnetic field at the surface of magnetization element 11 and/or with regard to the field strength at the surface of the magnetization element. Other codings are possible.

The sensor 12 can be configured to detect when a boundary between adjacent sections 41, 42 is led past the sensor 12. As a result, changes of the relative position between the marking element 11 and the sensor 12 can be monitored. The processing unit 13 can further evaluate the sensed changes of the relative position.

FIG. 6 shows a marking element 11 having a magnetization pattern 50. The magnetization pattern 50 defines an absolute coding. The magnetization pattern 50 has a sequence of sections 51-58 of different magnetization. The sections 51-58 are arranged in a sequence at least along a direction 59. The magnetization and/or the magnetic field strength of each of the sections 51-58 may be unique in the sequence of sections 51-58. That is to say, different sections 51-58 which are arranged along the direction 59 each have different magnetic properties, which can be read by the sensor 12. This allows the sensor 12 to determine which of the sections 51-58 is currently positioned closest to the sensor.

In the use of the device 10, the direction 59 can be aligned with the movement direction 8 of the movable switching element 1. On attachment to a rotatably mounted part 4 of the electric switch, the longitudinal direction 59 of the marking element 11 can at least partly rotate about the axis of rotation 5.

The sections 51-58 which form different magnetic markings can be permanent-magnetic. The sections 51-58 which form different magnetic marks may differ with regard to the polarity of the magnetic field at the surface of magnetization element 11 and/or with regard to the field strength at the surface of the magnetization element 11 and/or with regard to a magnetic field pattern over the corresponding section 51-58. Other codings are possible. For example, in each of the sections 51-58 a sequence of a plurality of magnetic particles may be arranged or embedded, which binary-code a number and uniquely identify the section 51-58. The sensor 12 can be adapted to read the coding.

The sensor 12 can be adapted to detect which of the sections 51-58 is currently positioned in front of the sensor. From the absolute positions thus known, changes of the relative position between the marking element 11 and the sensor 12 can be monitored. The processing unit 13 can further evaluate the detected changes of the relative position.

While exemplary embodiments have been described in detail with reference to the figures, alternative or additional features may be used in further exemplary embodiments. While, for example, a strip-shaped marking element has been described, the marking element having a plurality of magnetic markings may also have a different shape. While devices and methods have been described, in which the marking element is attached to a movable part of the switch and the sensor is attached to a stationary part of the switch, the marking element may be attached to a stationary part of the switch and the sensor may be attached to a movable part of the switch.

Methods and devices according to exemplary embodiments can be used in particular for checking electric switches in the field, without being limited thereto.

1. A method for checking a switching operation of an electric switch, comprising:
sensing a movement of a movable switching element of the electric switch during the switching operation using a marking element, the marking element having a magnetization pattern comprising a plurality of magnetic markings, and the sensing of the movement comprising:
determining a path length of a relative movement between the marking element and a sensor, the method further comprising:
detachably fastening the sensor to a fixed frame of the electric switch,
the sensor being fastened to the frame by a lockable movable fastening device and positioned in the vicinity of the marking element,
the fastening device comprising a movable arm which comprises at least one rigid element and at least one lockable ball joint.

2. The method according to claim 1, comprising:
detachably attaching the marking element to the electric switch by a detachable holding device.

3. The method according to claim 1, wherein the marking element is reversibly detachably attached to the movable switching element or to a component of the switch, which component moves on the movement of the movable switching element.

4. The method according to claim 1, wherein the magnetization pattern has a pattern of magnetic markings periodically repeating along a direction, the direction being arranged parallel to a movement direction of the movable switching element.

5. The method according to claim 1, wherein the magnetization pattern is absolutely coded.

6. The method of claim 1 wherein the electric switch is an electric power switch or an electric load switch.

7. Device for checking a switching operation of an electric switch which has a movable switching element, the device comprising:
a marking element which has a magnetization pattern comprising a plurality of magnetic markings,
a sensor for sensing a relative movement between the marking element and the sensor,
a processing unit which is coupled to the sensor and which is adapted to determine a path length of the relative movement sensed by the sensor, and
a lockable movable fastening device for detachably fastening the sensor to a frame of the electric switch, the fastening device comprising a movable arm which comprises at least one rigid element and at least one lockable ball joint.

8. Device according to claim 7, comprising a holding device for reversibly detachably attaching the marking element to the movable switching element or to a component of the electric switch, which component moves on a movement of the movable switching element.

9. Device according to claim 7, wherein the magnetization pattern has a pattern of magnetic markings periodically repeating along a direction.

10. Device according to claim 7, wherein the magnetization pattern is absolutely coded.

11. Device according to claim 7, the fastening device comprising at least one further arm for supporting the sensor.

12. Device according to claim 7, wherein the device is configured to check a switching operation of an electric power switch or an electric load switch.
